(19) United States
(12) Patent Application Publication
(10) Pub. No.: US 2026/0271463 A1
(43) Pub. Date: Sep. 10, 2026

(54) DISPLAY DEVICE AND ELECTRONIC DEVICE INCLUDING THE SAME

(71) Applicant: Samsung Display Co., LTD., Yongin-si (KR)

(72) Inventor: Seul Ki LEE, Yongin-si (KR)

(21) Appl. No.: 19/328,938

(22) Filed: Sep. 15, 2025

(30) Foreign Application Priority Data
Mar. 5, 2025 (KR) 10-2025-0028030

(51) Int. Cl. H10H 29/853; H10H 29/85

(52) U.S. Cl. CPC H10H 29/853; H10H 29/8582

(57) ABSTRACT

A display device includes a display panel, a panel protection member arranged on a major surface of the display panel in a first direction, a panel support member arranged on a major surface of the panel protection member in a second direction opposite to the first direction, a spacer arranged on a major surface of the panel support member in the first direction, an adhesive member arranged on the major surface of the panel support member in the first direction and spaced apart from the spacer, and a heat dissipation member arranged on the major surface of the panel support member in the first direction to surround sides of the spacer and the adhesive member.

This application claims priority to Korean Patent Application No. 10-2025-0028030, filed on Mar. 05, 2025, and all the benefits accruing therefrom under 35 U.S.C. 119, the content of which in its entirety is herein incorporated by reference.

### BACKGROUND

### Technical Field

The present disclosure relates to a display device and an electronic device including the same.

### Description of the Related Art

In general, electronic devices such as smart phones, tablet PCs, digital cameras, laptop computers, navigation systems and smart TVs include display devices for displaying images.

The display device includes a plurality of light emitting elements, and the plurality of light emitting elements may display an image through a power source applied from the outside. A portion of the power source, which is applied to the plurality of light emitting elements and is not converted into light energy, may be accumulated in the display device as heat energy. Heat accumulated in the display device is one of main factors that deteriorate display quality of the display device.

With high performance of the display device, internal electronic components of the display device become highly integrated, and as the high integration of the electronic components progresses, heat density increases, thereby requiring a technology for more effectively removing heat generated inside the display device.

In addition, as the display device becomes smaller, a technology for reducing a thickness of the display device is desirable.

### SUMMARY

An aspect of the present disclosure is to provide a display device capable of reducing its thickness and effectively removing heat generated inside the display device, and an electronic device including the same.

The aspects of the present disclosure are not limited to those mentioned above and additional aspects of the present disclosure, which are not mentioned herein, will be clearly understood by those skilled in the art from the following description of the present disclosure.

According to an aspect of the present disclosure, a display device includes a display panel, a panel protection member arranged on a first major surface of the display panel in a first direction, a panel support member arranged on a major surface of the panel protection member in a second direction opposite to the first direction, a spacer arranged on a major surface of the panel support member in the first direction, an adhesive member arranged on the major surface of the panel support member in the first direction and spaced apart from the spacer, and a heat dissipation member arranged on the major surface of the panel support member in the first direction to surround sides of the spacer and the adhesive member.

A thickness of the heat dissipation member may be thinner than each of a thickness of the spacer and a thickness of the adhesive member.

The side of the spacer and the side of the adhesive member may be spaced apart from a side of the heat dissipation member.

The heat dissipation member may be arranged to cover at least a portion of the major surface of the panel support member in the first direction.

The display panel may be partitioned into a first non-bending area, a second non-bending area, and a bending area formed between the first non-bending area and the second non-bending area, the display device further may include a bending protection member arranged on a second major surface of the display panel, which is opposite to the first major surface of the display panel, in the bending area of the display panel, and a circuit board connected to the display panel.

The spacer may be in contact with the panel protection member arranged on the first major surface of the display panel in the second non-bending area.

The circuit board may be connected to the second non-bending area of the display panel, and the adhesive member may be in contact with the circuit board.

The display device may further include a driving circuit arranged on the second major surface of the display panel in the second non-bending area, a cover member covering the driving circuit, a polarizing film arranged on the second major surface of the display panel in the first non-bending area, and a cover window arranged on a major surface of the polarizing film in the second direction.

According to an aspect of the present disclosure, a display device includes a display panel, a panel protection member arranged on a first major surface of the display panel in a first direction, a panel support member arranged on a major surface of the panel protection member in a second direction opposite to the first direction, a heat dissipation member arranged on a major surface of the panel support member in the first direction, a spacer arranged on a major surface of the heat dissipation member in the first direction, an adhesive member arranged on the major surface of the heat dissipation member in the first direction and spaced apart from the spacer, and an auxiliary heat dissipation member arranged on the major surface of the heat dissipation member in the first direction to surround sides of the spacer and the adhesive member.

A thickness of the auxiliary heat dissipation member may be thinner than each of a thickness of the spacer and a thickness of the adhesive member.

A thickness of the auxiliary heat dissipation member may be thicker than a thickness of the heat dissipation member.

The side of the spacer and the side of the adhesive member may be spaced apart from a side of the heat dissipation member.

The heat dissipation member may be arranged to cover the major surface of the panel support member in the first direction.

The display panel may be partitioned into a first non-bending area, a second non-bending area, and a bending area formed between the first non-bending area and the second non-bending area, and the display device may further include a bending protection member arranged on a second major surface of the display panel, which is opposite to the first major surface of the display panel, in the bending area of the display panel, and a circuit board connected to the display panel.

The spacer may be in contact with the panel protection member arranged on the first major surface of the display panel in the second non-bending area.

The circuit board may be connected to the second non-bending area of the display panel, and the adhesive member may be in contact with the circuit board.

The display device may further include a driving circuit arranged on the second major surface of the display panel in the second non-bending area, a cover member covering the driving circuit, a polarizing film arranged on the second major surface e of the display panel in the first non-bending area, and a cover window arranged on a major surface of the polarizing film in the second direction.

According to an aspect of the present disclosure, an electronic device includes a display panel, a panel protection member arranged on a major surface of the display panel in a first direction, a panel support member arranged on a major surface of the panel protection member in a second direction opposite to the first direction, a spacer arranged on a major surface of the panel support member in the first direction, an adhesive member arranged on the major surface of the panel support member in the first direction and spaced apart from the spacer, a heat dissipation member arranged on the major surface of the panel support member in the first direction, a processor, a memory in which one or more data of the display panel and the processor are stored, and a power module, which supplies a power source to the display panel, the processor, and the memory.

The heat dissipation member may be arranged to surround sides of the spacer and the adhesive member.

The spacer and the adhesive member may be arranged on a major surface of the heat dissipation member in the first direction, and the electronic device may further include an auxiliary heat dissipation member arranged on the major surface of the heat dissipation member in the first direction to surround sides of the spacer and the adhesive member.

According to the display device and the electronic device including the same of the present disclosure, a spacer and a portion of an adhesive member are buried in a heat dissipation member so that a thickness of the display device may be effectively reduced, and an auxiliary heat dissipation member is arranged below the heat dissipation member so that heat generated inside the display device may be effectively removed.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan view illustrating an unfolded state of a display panel of a display device according to the first embodiment of the present disclosure;

FIG. 2 is a plan view illustrating a bent state of a display panel of a display device according to the first embodiment of the present disclosure;

FIG. 3 is a cross-sectional view taken along line I1-I1’ of FIG. 1;

FIG. 4 is a cross-sectional view taken along line I2-I2’ of FIG. 2;

FIG. 5 is an enlarged view of a portion A of FIG. 1;

FIG. 6 is an enlarged view of a portion B of FIG. 5;

FIG. 7 is an enlarged view of a portion C of FIG. 5;

FIG. 8 is an enlarged view of a portion D of FIG. 5;

FIG. 9 is a plan view illustrating an unfolded state of a display panel of a display device according to the second embodiment of the present disclosure;

FIG. 10 is a plan view illustrating a bent state of a display panel of a display device according to the second embodiment of the present disclosure;

FIG. 11 is a cross-sectional view taken along line I3-I3’ of FIG. 9;

FIG. 12 is a cross-sectional view taken along line I4-I4’ of FIG. 10;

FIG. 13 is an enlarged view of a portion E of FIG. 9;

FIG. 14 is an enlarged view of a portion F of FIG. 13;

FIG. 15 is an enlarged view of a portion G of FIG. 13;

FIG. 16 is an enlarged view of a portion H of FIG. 13;

FIG. 17 is a block diagram illustrating an electronic device according to one embodiment; and

FIG. 18 illustrates schematic diagrams of electronic devices according to various embodiments.

### DETAILED DESCRIPTION

Advantages and features of the present disclosure and methods to achieve them will become apparent from the descriptions of example embodiments hereinbelow with reference to the accompanying drawings. However, the present disclosure is not limited to example embodiments disclosed herein but may be implemented in various different ways. The example embodiments are provided for making the disclosure of the present disclosure thorough and for fully conveying the scope of the present disclosure to those skilled in the art. It is to be noted that the scope of the present disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Although terms such as “first”, “second”, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the present disclosure.

Features of various example embodiments of the present disclosure may be combined partially or totally. As will be clearly appreciated by those skilled in the art, technically various interactions and operations are possible. Various example embodiments can be practiced individually or in combination.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, example embodiments of the present disclosure will be described in detail with reference to the accompanying drawings.

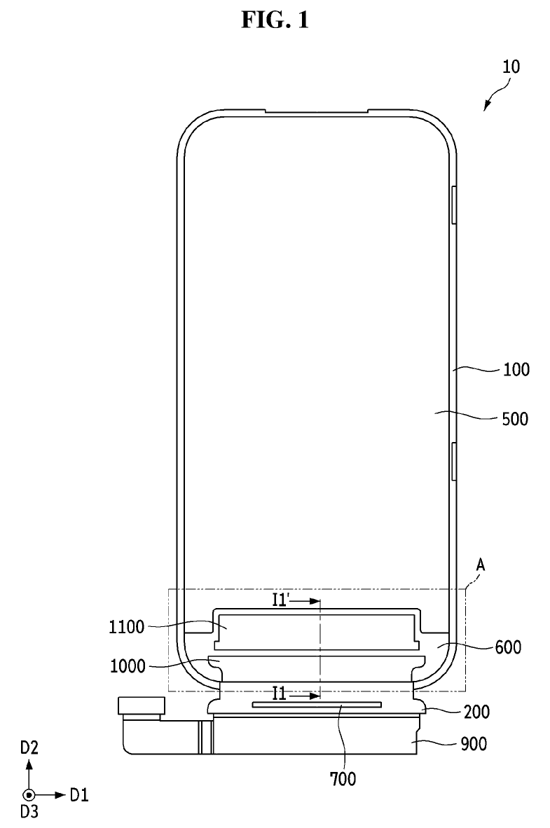

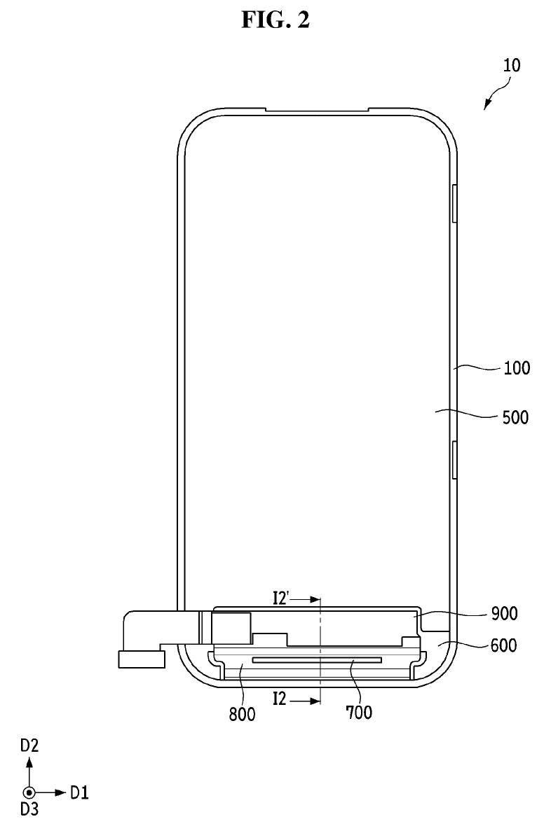

FIG. 1 is a plan view illustrating an unfolded state of a display panel of a display device according to the first embodiment of the present disclosure. FIG. 2 is a plan view illustrating a bent state of a display panel of a display device according to the first embodiment of the present disclosure. As used herein, the “plan view” is a view in a thickness direction (i.e., third direction D3) of the display device.

Referring to FIGS. 1 and 2, a display device 10 according to the first embodiment of the present disclosure may be a light emitting display device such as an organic light emitting display device using an organic light emitting diode, a quantum dot light emitting display device including a quantum dot light emitting layer, an inorganic light emitting display device including an inorganic semiconductor and a micro light emitting display device using a micro light emitting diode. The following description will be based on that the display device 10 is an organic light emitting display device, but the present disclosure is not limited thereto.

A planar shape of the display device 10 may have a rectangular shape such as a rectangle. For example, the display device 10 may have a rectangular planar shape having a short side in a first direction D1 and a long side in a second direction D2. A corner at which the short side in the first direction D1 and the long side in the second direction D2 meet may be rounded to have a curvature, or may be formed at a right angle. The planar shape of the display device 10 is not limited to a rectangle, but may be formed in another polygonal shape, a circular shape, or an oval shape.

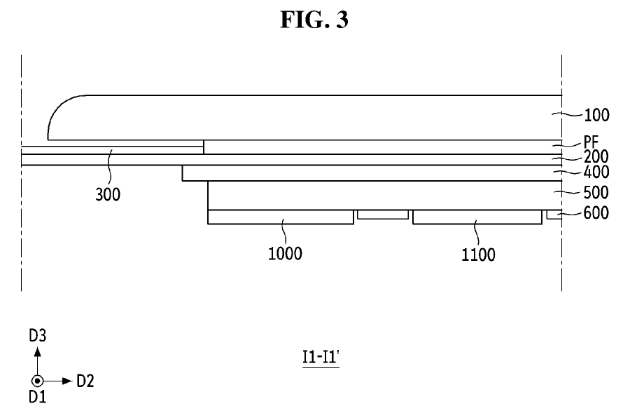

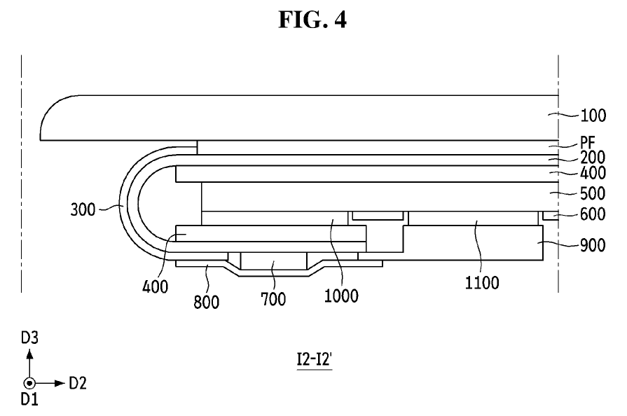

FIG. 3 is a cross-sectional view taken along line I1-I1’ of FIG. 1. FIG. 4 is a cross-sectional view taken along line I2-I2’ of FIG. 2.

Referring to FIGS. 3 and 4, the display device 10 according to the first embodiment of the present disclosure may include a cover window 100, a polarizing film PF, a display panel 200, a bending protection member 300, a panel protection member 400, a panel support member 500, a heat dissipation member 600, a driving circuit 700, a cover member 800, a circuit board 900, a spacer 1000, and an adhesive member 1100.

The cover window 100 may be arranged on the polarizing film PF to cover an upper surface of the polarizing film PF in a third direction D3. The cover window 100 may serve to protect the upper surface of the polarizing film PF. The cover window 100 may include a transmissive portion for transmitting light and a light blocking portion for blocking light. As used herein, an upper surface or a lower surface of a panel, member, film, or spacer is referred to as “major surface” to be distinguished from a “side” of the panel, member, film, or spacer. The major surface (except for that of the bending protection member 300) may face the third direction D3, while the side may face a direction perpendicular to the third direction D3 (e.g., first direction D1 or second direction D2).

The cover window 100 may include a material having high light transmittance. The cover window 100 may include a polymer resin such as polyimide or glass.

The polarizing film PF may be arranged on the display panel 200. The polarizing film PF may serve to prevent image visibility of the display panel 200 from deteriorating due to reflection of external light. The polarizing film PF may include a linearly polarizing plate and a phase delay film such as a λ/4 (quarter-wave) plate. The phase delay film may be arranged on the display panel 200, and the linearly polarizing plate may be arranged on the phase delay film. The cover window 100 may be arranged on the polarizing film PF.

The display panel 200 may be arranged below the polarizing film PF. The display panel 200 may have a rectangular planar shape having sides in the first direction D1 and sides in the second direction D2. In the display panel 200, a corner at which the side in the first direction D1 and the side in the second direction D2 meet may be formed at a right angle, or may be rounded to have a curvature. The display panel 200 may have a planar shape such as a polygonal shape other than the rectangular shape, circular shape, an oval shape or an atypical shape.

The display panel 200 may include a display area in which a plurality of light emission areas for emitting light are arranged and a non-display area arranged around the display area. The non-display area may be arranged to surround the display area. A plurality of display pads may be arranged in the non-display area at an edge of one side of the display panel 200. The display panel 200 may be partitioned into a non-bending area and a bending area. For example, the display panel 200 may be partitioned into a first non-bending area, a second non-bending area, and a bending area formed between the first and second non-bending areas.

The display panel 200 may include a substrate, a display unit, and a sensor unit.

The substrate may be made of an insulating material such as glass, quartz and polymer resin. The substrate may be a rigid substrate or a flexible substrate capable of being subjected to bending, folding, rolling, etc.

The display unit may be arranged on the substrate. The display unit may be a layer including a plurality of light emission areas for emitting light. The display unit may include a buffer film, a thin film transistor layer in which thin film transistors are arranged, a light emitting element layer for emitting light, and an encapsulation layer for encapsulating the light emitting element layer.

The sensor unit may be arranged on the display unit. The sensor unit includes sensor electrodes, and may be a layer for sensing whether there is a user’s touch.

The bending protection member 300 may be arranged on the bending area of the display panel 200. For example, the bending protection member 300 may be arranged on the display panel 200 to cover the bending area. A portion of the bending protection member 300 may overlap a portion of the display area and a pad area of the display panel 200, but is not limited thereto, and the bending protection member 300 may overlap only the bending area.

The bending protection member 300 may protect the bending area of the display panel 200. For example, the bending protection member 300 may protect a conductive layer in the bending area of the display panel 200. Lines for transmitting a driving signal to the display panel 200 may be arranged in the conductive layer in the bending area of the display panel 200. A position of a stress neutral plane when the display panel 200 is bent may be adjusted depending on the arrangement of the bending protection member 300, so that tensile stress applied to the conductive layer may be minimized. Also, the bending protection member 300 may protect the bending area of the display panel 200 from static electricity introduced from the outside.

The panel protection member 400 may be arranged below the display panel 200 in the third direction D3. The panel protection member 400 may absorb an external impact transferred from a lower portion of the display panel 200 to the display panel 200. In some embodiments, the panel protection member 400 may protect the display panel 200 from the external impact.

The panel protection member 400 may be arranged on the non-bending area of the display panel 200. For example, the panel protection member 400 may be arranged below the first and second non-bending areas of the display panel 200.

The panel protection member 400 may include a single layer or a plurality of layers. For example, the panel protection member 400 may include a polymer resin such as polyurethane, polycarbonate, polypropylene or polyethylene, or may include a material having elasticity such as rubber, a urethane-based material, or a sponge formed by foaming an acrylic-based material.

The panel support member 500 may be arranged below the panel protection member 400. The panel support member 500 may be a rigid member of which shape or volume is not easily changed by external pressure. The panel support member 500 is arranged below the display panel 200, and is a rigid member of which shape or volume is not easily changed by external pressure and thus may support the display panel 200.

In one embodiment, the panel support member 500 may be a metal plate. For example, the panel support member 500 may be made of metal or a metal alloy as a metal plate. The panel support member 500 may include copper (Cu), aluminum (Al), stainless steel (SUS), and/or their alloy, but is not limited thereto.

In another embodiment, the panel support member 500 may be a polymer containing carbon fibers or glass fibers. In this case, since the panel support member 500 includes a polymer containing carbon fibers or glass fibers, when the display device 10 includes a digitizer member, an electromagnetic signal of the digitizer member may pass through the panel support member 500. Therefore, the panel support member 500 capable of supporting the display panel 200 without lowering touch sensitivity of the digitizer member may be provided.

The heat dissipation member 600 may be arranged below the panel support member 500. The heat dissipation member 600 may include a metal thin film such as copper, nickel, ferrite, or silver, which has excellent thermal conductivity. The heat dissipation member 600 may serve to dissipate heat generated from the display panel 200 to the outside of the display panel 200. The heat dissipation member 600 may be arranged below the panel support member 500 to overlap the first non-bending area adjacent to the bending area of the display panel 200.

A groove for burying the spacer 1000 and the adhesive member 1100 may be formed in the heat dissipation member 600. Since the spacer 1000 and the adhesive member 1100 are buried in the groove of the heat dissipation member 600, the heat dissipation member 600 may be arranged to surround sides of the spacer 1000 and the adhesive member 1100. The heat dissipation member 600 may be arranged to surround the spacer 1000 and the adhesive member 1100 in a state of being spaced apart from the sides of the spacer 1000 and the adhesive member 1100. In some embodiments, a gap space may be formed among the side of the heat dissipation member 600, the side of the spacer 1000, and the side of the adhesive member 1100. The heat dissipation member 600 may be formed to have a thickness less than each of a thickness of the spacer 1000 and a thickness of the adhesive member 1100.

The driving circuit 700 may be arranged on the display panel 200 in the second non-bending area of the display panel 200. The driving circuit 700 may generate and output data voltages, power voltages, scan timing signals, and the like. The driving circuit 700 may be arranged on the second non-bending area of the display panel 200, but is not limited thereto.

The cover member 800 may cover the driving circuit 700. The cover member 800 may be arranged on the second non-bending area of the display panel 200 to cover the driving circuit 700. The cover member 800 may be arranged to cover a portion of the bending protection member 300 and a portion of the circuit board 900. For example, the cover member 800 may extend from one end of the bending protection member 300 to one end of the circuit board 900. The cover member 800 may protect the driving circuit 700 from the external impact.

The circuit board 900 may process a signal converted by a signal unit (not shown) and transmit the signal to the display panel 200. The circuit board 900 may be electrically connected to the second non-bending area of the display panel 200.

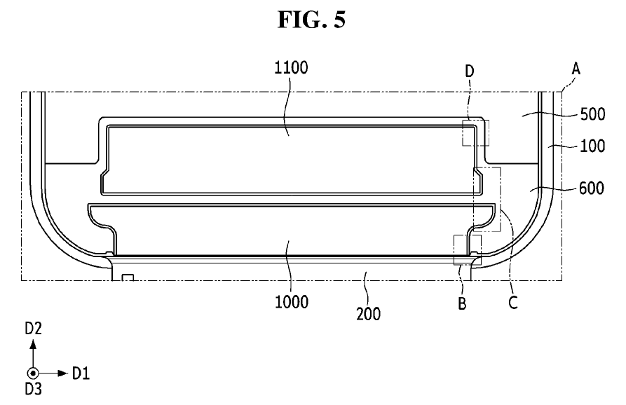

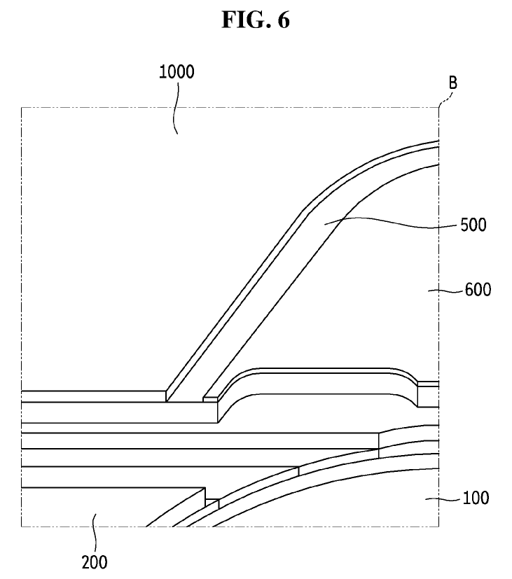

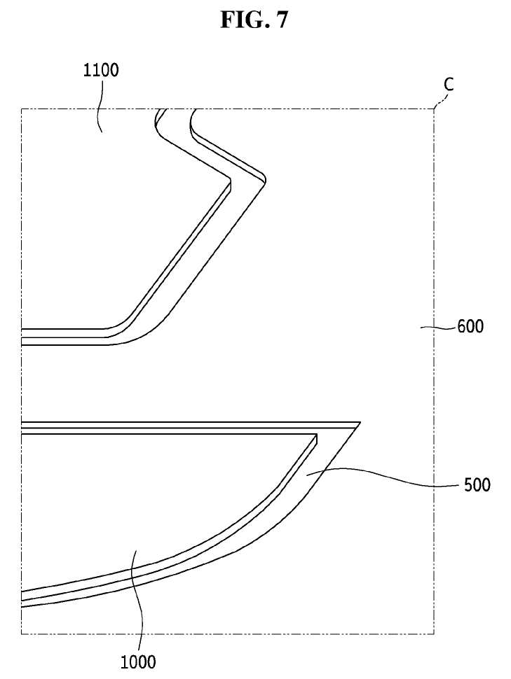

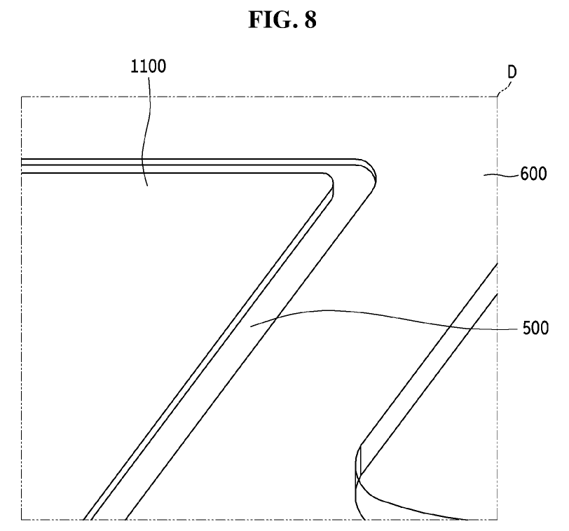

FIG. 5 is an enlarged view of a portion A of FIG. 1. FIG. 6 is an enlarged view of a portion B of FIG. 5. FIG. 7 is an enlarged view of a portion C of FIG. 5. FIG. 8 is an enlarged view of a portion D of FIG. 5.

Referring to FIGS. 5 to 8, the spacer 1000 may be arranged below the panel support member 500. The spacer 1000 may be arranged below the panel support member 500 to overlap the first non-bending area adjacent to the bending area of the display panel 200. The thickness of the spacer 1000 may be greater than the thickness of the heat dissipation member 600. The side of the spacer 1000 may be surrounded by the heat dissipation member 600. The side of the spacer 1000 may be spaced apart from the side of the heat dissipation member 600, so that a gap space may be formed between the side of the spacer 1000 and the side of the heat dissipation member 600.

When the display panel 200 is bent, the spacer 1000 may be in contact with the panel protection member 400 arranged below the second non-bending area of the display panel 200. In some embodiments, when the display panel 200 is bent, the spacer 1000 may serve to fill a space between the panel support member 500 and the panel protection member 400 arranged below the second non-bending area of the display panel 200. As a result, the bending area of the display panel 200 may be prevented from being excessively deformed.

The adhesive member 1100 may be arranged below the panel support member 500 and spaced apart from the spacer 1000. For example, the adhesive member 1100 may be arranged below the panel support member 500 and spaced apart from the spacer 1000 in the second direction D2. The thickness of the adhesive member 1100 may be greater than the thickness of the heat dissipation member 600, and may be equal to the thickness of the spacer 1000. The side of the adhesive member 1100 may be surrounded by the heat dissipation member 600. The side of the adhesive member 1100 may be spaced apart from the side of the heat dissipation member 600, so that a gap space may be formed between the side of the adhesive member 1100 and the side of the heat dissipation member 600.

The adhesive member 1100 may come into contact with the circuit board 900 when the display panel 200 is bent. The adhesive member 1100 may serve to fix the circuit board 900 in contact with the circuit board 900.

The display device 10 according to the first embodiment of the present disclosure may reduce the overall thickness of the display device 10 by burying a portion of the spacer 1000 and the adhesive member 1100 in the heat dissipation member 600. Since the overall thickness of the display device 10 is reduced, the curvature of the bending area of the display panel 200 may be reduced.

Hereinafter, a display device according to the second embodiment of the present disclosure will be described with reference to the drawings.

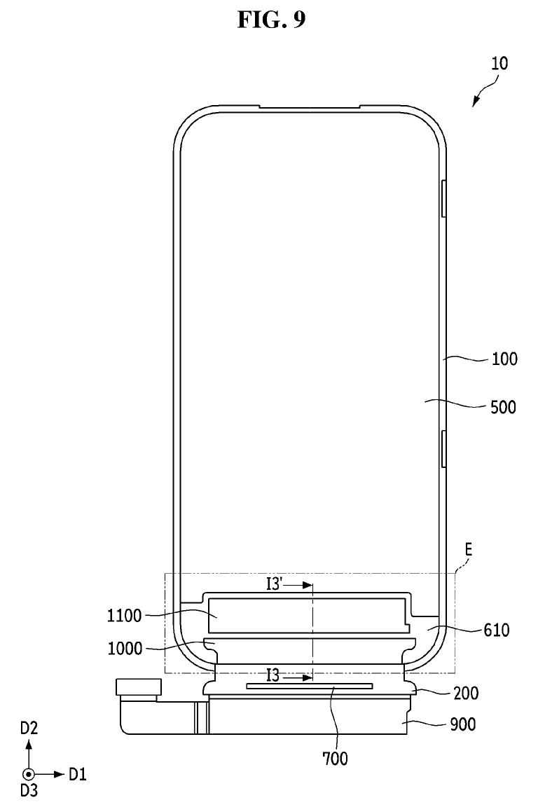

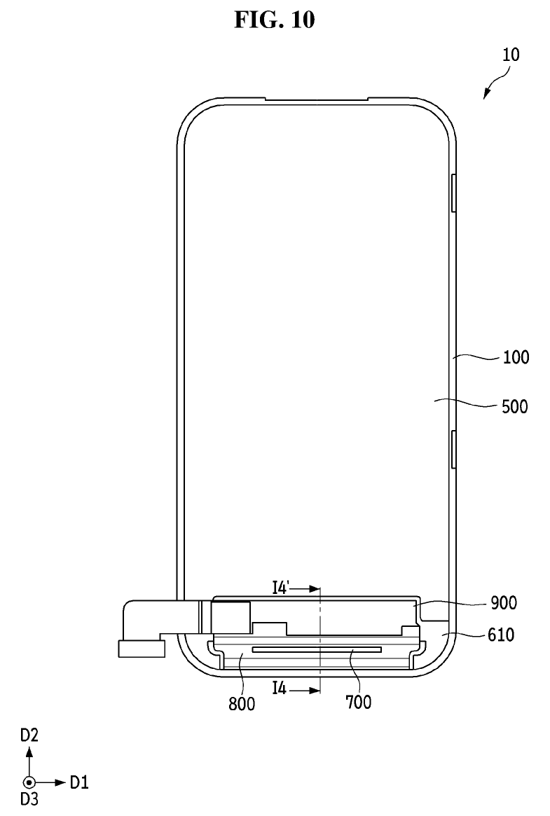

FIG. 9 is a plan view illustrating an unfolded state of a display panel of a display device according to the second embodiment of the present disclosure. FIG. 10 is a plan view illustrating a bent state of a display panel of a display device according to the second embodiment of the present disclosure.

Referring to FIGS. 9 and 10, a display device 10 according to the second embodiment of the present disclosure may be a light emitting display device such as an organic light emitting display device using an organic light emitting diode, a quantum dot light emitting display device including a quantum dot light emitting layer, an inorganic light emitting display device including an inorganic semiconductor and a micro light emitting display device using a micro light emitting diode. The following description will be based on that the display device 10 is an organic light emitting display device, but the present disclosure is not limited thereto.

A planar shape of the display device 10 may have a rectangular shape such as a rectangle. For example, the display device 10 may have a rectangular planar shape having a short side in a first direction D1 and a long side in a second direction D2. A corner at which the short side in the first direction D1 and the long side in the second direction D2 meet may be rounded to have a curvature, or may be formed at a right angle. The planar shape of the display device 10 is not limited to a rectangle, but may be formed in another polygonal shape, a circular shape, or an oval shape.

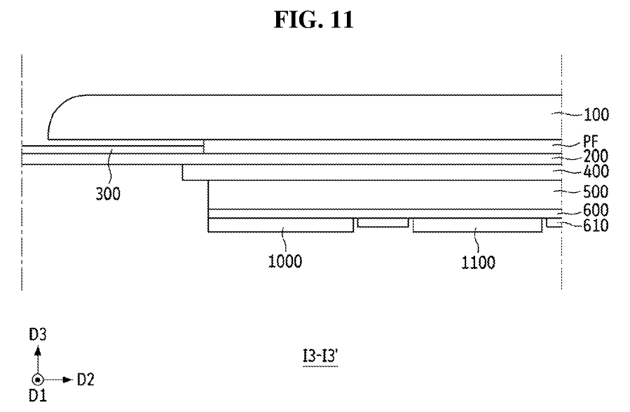

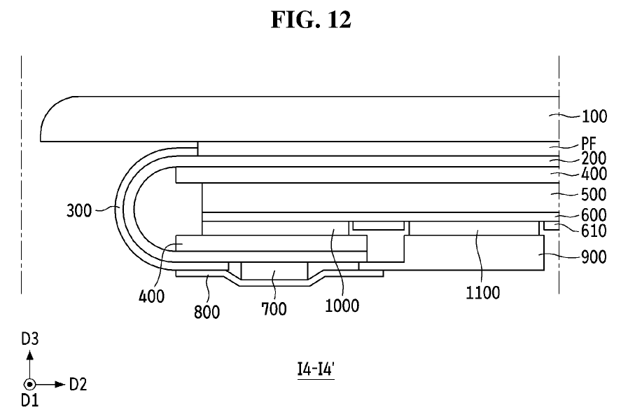

FIG. 11 is a cross-sectional view taken along line I3-I3’ of FIG. 9. FIG. 12 is a cross-sectional view taken along line I4-I4’ of FIG. 12.

Referring to FIGS. 11 and 12, the display device 10 according to the second embodiment of the present disclosure may include a cover window 100, a polarizing film PF, a display panel 200, a bending protection member 300, a panel protection member 400, a panel support member 500, a heat dissipation member 600, an auxiliary heat dissipation member 610, a driving circuit 700, a cover member 800, a circuit board 900, a spacer 1000, and an adhesive member 1100.

The cover window 100 may be arranged on the polarizing film PF to cover an upper surface of the polarizing film PF in a third direction D3. The cover window 100 may serve to protect the upper surface of the polarizing film PF. The cover window 100 may include a transmissive portion for transmitting light and a light blocking portion for blocking light.

The cover window 100 may include a material having high light transmittance. The cover window 100 may include a polymer resin such as polyimide or glass.

The polarizing film PF may be arranged on the display panel 200. The polarizing film PF may serve to prevent image visibility of the display panel 200 from deteriorating due to reflection of external light. The polarizing film PF may include a linearly polarizing plate and a phase delay film such as a λ/4 (quarter-wave) plate. The phase delay film may be arranged on the display panel 200, and the linearly polarizing plate may be arranged on the phase delay film. The cover window 100 may be arranged on the polarizing film PF.

The display panel 200 may be arranged below the polarizing film PF. The display panel 200 may have a rectangular planar shape having sides in the first direction D1 and sides in the second direction D2. In the display panel 200, a corner at which the side in the first direction D1 and the side in the second direction D2 meet may be formed at a right angle, or may be rounded to have a curvature. The display panel 200 may have a planar shape such as a polygonal shape other than the rectangular shape, circular shape, an oval shape or an atypical shape.

The display panel 200 may include a display area in which a plurality of light emission areas for emitting light are arranged and a non-display area arranged around the display area. The non-display area may be arranged to surround the display area. A plurality of display pads may be arranged in the non-display area at an edge of one side of the display panel 200. The display panel 200 may be partitioned into a non-bending area and a bending area. For example, the display panel 200 may be partitioned into a first non-bending area, a second non-bending area, and a bending area formed between the first and second non-bending areas.

The display panel 200 may include a substrate, a display unit, and a sensor unit.

The substrate may be made of an insulating material such as glass, quartz and polymer resin. The substrate may be a rigid substrate or a flexible substrate capable of being subjected to bending, folding, rolling, etc.

The display unit may be arranged on the substrate. The display unit may be a layer including a plurality of light emission areas for emitting light. The display unit may include a buffer film, a thin film transistor layer in which thin film transistors are arranged, a light emitting element layer for emitting light, and an encapsulation layer for encapsulating the light emitting element layer.

The sensor unit may be arranged on the display unit. The sensor unit includes sensor electrodes, and may be a layer for sensing whether there is a user’s touch.

The bending protection member 300 may be arranged on the bending area of the display panel 200. For example, the bending protection member 300 may be arranged on the display panel 200 to cover the bending area. A portion of the bending protection member 300 may overlap a portion of the display area and a pad area of the display panel 200, but is not limited thereto, and the bending protection member 300 may overlap only the bending area.

The bending protection member 300 may protect the bending area of the display panel 200. For example, the bending protection member 300 may protect a conductive layer in the bending area of the display panel 200. Lines for transmitting a driving signal to the display panel 200 may be arranged in the conductive layer in the bending area of the display panel 200. A position of a stress neutral plane when the display panel 200 is bent may be adjusted depending on the arrangement of the bending protection member 300, so that tensile stress applied to the conductive layer may be minimized. Also, the bending protection member 300 may protect the bending area of the display panel 200 from static electricity introduced from the outside.

The panel protection member 400 may be arranged below the display panel 200 in the third direction D3. The panel protection member 400 may absorb an external impact transferred from a lower portion of the display panel 200 to the display panel 200. In some embodiments, the panel protection member 400 may protect the display panel 200 from the external impact.

The panel protection member 400 may be arranged on the non-bending area of the display panel 200. For example, the panel protection member 400 may be arranged below the first and second non-bending areas of the display panel 200.

The panel protection member 400 may include a single layer or a plurality of layers. For example, the panel protection member 400 may include a polymer resin such as polyurethane, polycarbonate, polypropylene or polyethylene, or may include a material having elasticity such as rubber, a urethane-based material, or a sponge formed by foaming an acrylic-based material.

The panel support member 500 may be arranged below the panel protection member 400. The panel support member 500 may be a rigid member of which shape or volume is not easily changed by external pressure. The panel support member 500 is arranged below the display panel 200, and is a rigid member of which shape or volume is not easily changed by external pressure and thus may support the display panel 200.

In one embodiment, the panel support member 500 may be a metal plate. For example, the panel support member 500 may be made of metal or a metal alloy as a metal plate. The panel support member 500 may include copper (Cu), aluminum (Al), stainless steel (SUS), and/or their alloy, but is not limited thereto.

In another embodiment, the panel support member 500 may be a polymer containing carbon fibers or glass fibers. In this case, since the panel support member 500 includes of a polymer containing carbon fibers or glass fibers, when the display device 10 includes a digitizer member, an electromagnetic signal of the digitizer member may pass through the panel support member 500. Therefore, the panel support member 500 capable of supporting the display panel 200 without lowering touch sensitivity of the digitizer member may be provided.

The heat dissipation member 600 may be arranged below the panel support member 500. The heat dissipation member 600 may include a metal thin film such as copper, nickel, ferrite, or silver, which has excellent thermal conductivity. The heat dissipation member 600 may serve to dissipate heat generated from the display panel 200 to the outside of the display panel 200. The heat dissipation member 600 may be arranged below the panel support member 500 to overlap the first non-bending area adjacent to the bending area of the display panel 200.

The auxiliary heat dissipation member 610 may be arranged below the heat dissipation member 600. The auxiliary heat dissipation member 610 may include a metal thin film such as copper, nickel, ferrite, or silver, which has excellent thermal conductivity. The auxiliary heat dissipation member 610 may be integrally formed with the heat dissipation member 600, or may be provided separately from the heat dissipation member 600 and stacked below the heat dissipation member 600.

A groove for burying the spacer 1000 and the adhesive member 1100 may be formed in the auxiliary heat dissipation member 610. Since the spacer 1000 and the adhesive member 1100 are buried in the groove of the auxiliary heat dissipation member 610, the auxiliary heat dissipation member 610 may be arranged to surround sides of the spacer 1000 and the adhesive member 1100. The auxiliary heat dissipation member 610 may be arranged to surround the spacer 1000 and the adhesive member 1100 in a state of being spaced apart from the sides of the spacer 1000 and the adhesive member 1100. In some embodiments, a gap space may be formed among the side of the auxiliary heat dissipation member 610, the side of the spacer 1000, and the side of the adhesive member 1100. The auxiliary heat dissipation member 610 may be formed to have a thickness less than each of a thickness of the spacer 1000 and a thickness of the adhesive member 1100 and greater than a thickness of the heat dissipation member 6100.

The driving circuit 700 may be arranged on the display panel 200 in the second non-bending area of the display panel 200. The driving circuit 700 may generate and output data voltages, power voltages, scan timing signals, and the like. The driving circuit 700 may be arranged on the second non-bending area of the display panel 200, but is not limited thereto.

The cover member 800 may cover the driving circuit 700. The cover member 800 may be arranged on the second non-bending area of the display panel 200 to cover the driving circuit 700. The cover member 800 may be arranged to cover a portion of the bending protection member 300 and a portion of the circuit board 900. For example, the cover member 800 may extend from one end of the bending protection member 300 to one end of the circuit board 900. The cover member 800 may protect the driving circuit 700 from the external impact.

The circuit board 900 may process a signal converted by a signal unit (not shown) and transmit the signal to the display panel 200. The circuit board 900 may be electrically connected to the second non-bending area of the display panel 200.

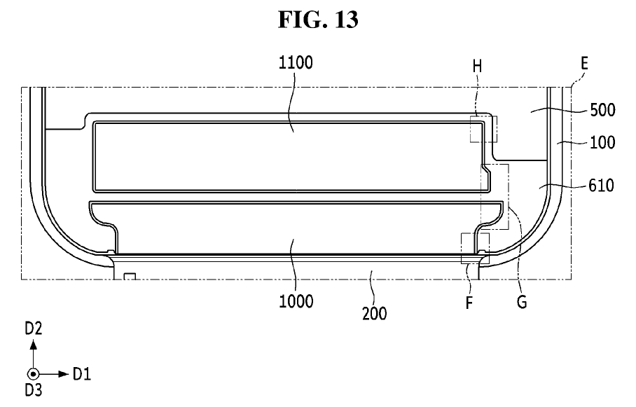

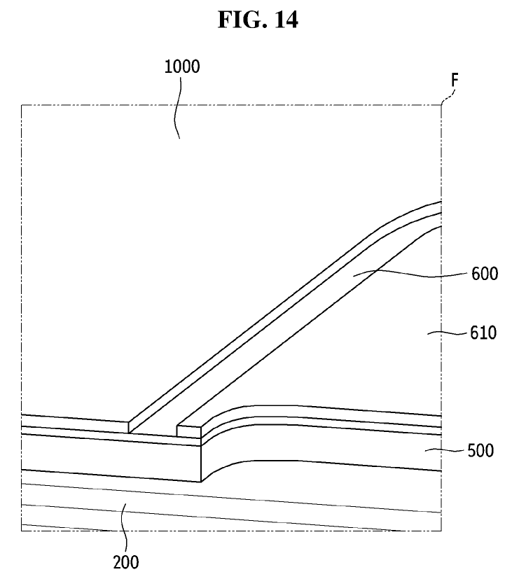

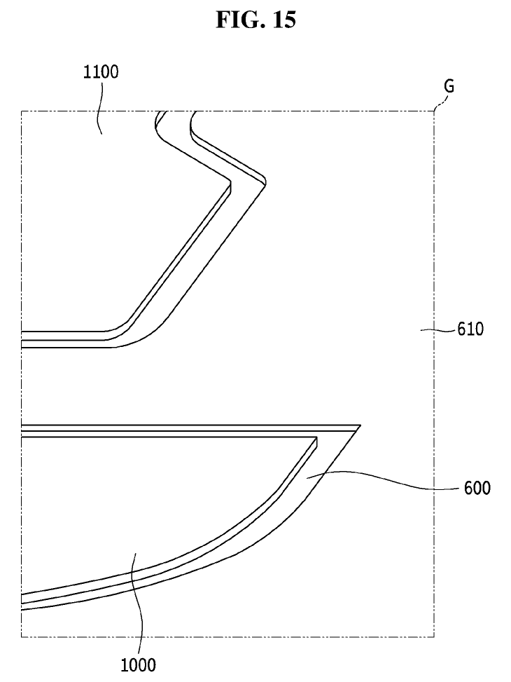

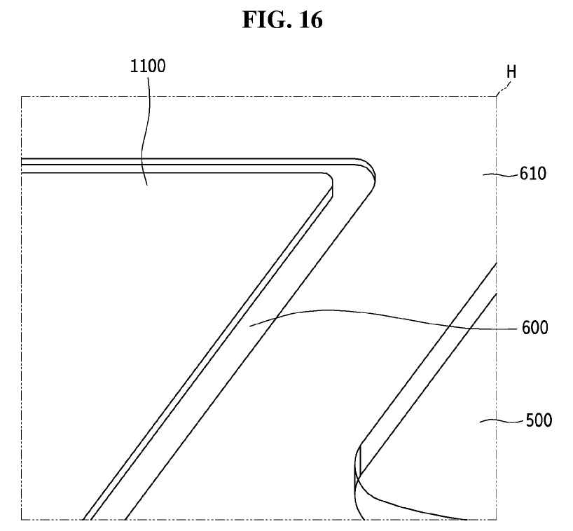

FIG. 13 is an enlarged view of a portion E of FIG. 9. FIG. 14 is an enlarged view of a portion F of FIG. 13. FIG. 15 is an enlarged view of a portion G of FIG. 13. FIG. 16 is an enlarged view of a portion H of FIG. 13.

Referring to FIGS. 13 to 16, the spacer 1000 may be arranged below the heat dissipation member 600. The spacer 1000 may be arranged below the heat dissipation member 600 to overlap the first non-bending area adjacent to the bending area of the display panel 200. The thickness of the spacer 1000 may be greater than the thickness of the auxiliary heat dissipation member 610. The side of the spacer 1000 may be surrounded by the auxiliary heat dissipation member 610. The side of the spacer 1000 may be spaced apart from the side of the auxiliary heat dissipation member 610, and a gap space may be formed between the side of the spacer 1000 and the side of the auxiliary heat dissipation member 610.

When the display panel 200 is bent, the spacer 1000 may be in contact with the panel protection member 400 arranged below the second non-bending area of the display panel 200. In some embodiments, when the display panel 200 is bent, the spacer 1000 may serve to fill a space between the heat dissipation member 600 and the panel protection member 400 arranged below the second non-bending area of the display panel 200. As a result, the bending area of the display panel 200 may be prevented from being excessively deformed.

The adhesive member 1100 may be arranged below the heat dissipation member 600 and spaced apart from the spacer 1000. For example, the adhesive member 1100 may be arranged below the heat dissipation member 600 and spaced apart from the spacer 1000 in the second direction D2. The thickness of the adhesive member 1100 may be greater than the thickness of the auxiliary heat dissipation member 610, and may be equal to the thickness of the spacer 1000. The side of the adhesive member 1100 may be surrounded by the auxiliary heat dissipation member 610. The side of the adhesive member 1100 may be spaced apart from the side of the auxiliary heat dissipation member 610, so that a gap space may be formed between the side of the adhesive member 1100 and the side of the auxiliary heat dissipation member 610.

The adhesive member 1100 may come into contact with the circuit board 900 when the display panel 200 is bent. The adhesive member 1100 may serve to fix the circuit board 900 in contact with the circuit board 900.

The display device 10 according to the second embodiment of the present disclosure may effectively discharge heat generated inside the display device 10 to the outside of the display device 10 by arranging the auxiliary heat dissipation member 610 below the heat dissipation member 600 to increase a heat dissipation area of the display device 10.

The display device according to the embodiments of the present disclosure may be applied to various electronic devices. An electronic device according to one embodiment includes the above-described display device, and may further include modules or devices, which have other additional functions, in addition to the display device.

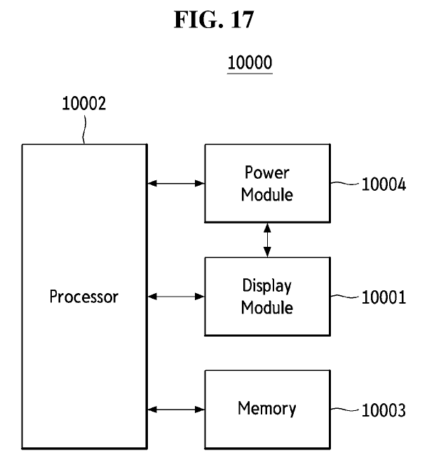

FIG. 17 is a block diagram illustrating an electronic device according to one embodiment.

Referring to FIG. 17, an electronic device 10000 according to one embodiment may include a display module 10001, a processor 10002, a memory 10003, and a power module 10004.

The processor 10002 may include at least one of a central processing unit (CPU), an application processor (AP), a graphic processing unit (GPU), a communication processor (CP), an image signal processor (ISP), or a controller.

Data information for an operation of the processor 10002 or the display module 10001 may be stored in the memory 10003. When the processor 10002 executes an application stored in the memory 10003, an image data signal and/or an input control signal is transmitted to the display module 10001, and the display module 10001 may process the received signal and output image information through a display screen.

The power module 10004 may include a power supply module such as a power adapter or a battery device, and a power conversion module that converts a power source supplied by the power supply module to generate a power source for the operation of the electronic device 10000.

At least one of the respective components of the above-described electronic device 10000 may be included in the display device according to the above-described embodiments. Also, some of the individual modules functionally included in one module may be included in the display device, and others thereof may be provided separately from the display device. For example, the display device includes the display module 10001, and the processor 10002, the memory 10003 and the power module 10004 may be provided as other devices in the electronic device 10000 not the display device.

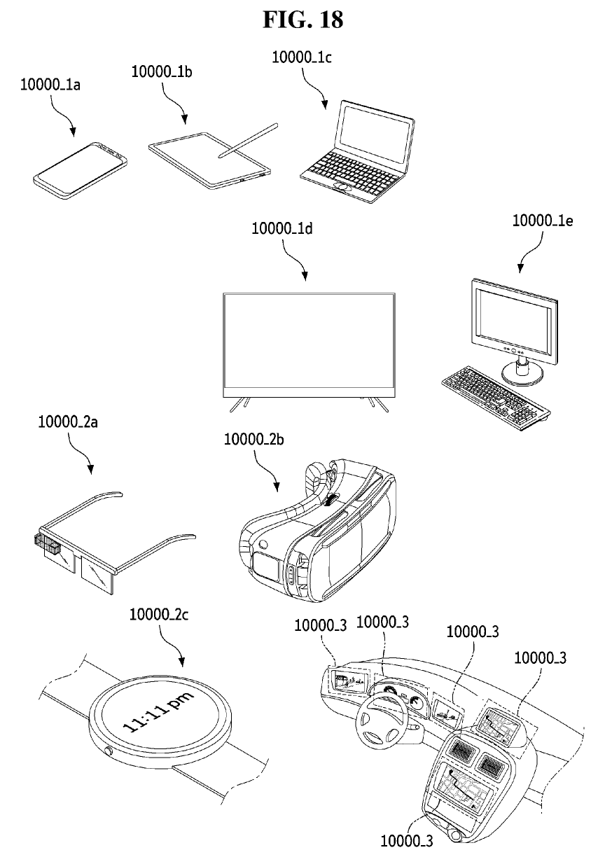

FIG. 18 illustrates schematic diagrams of electronic devices according to various embodiments.

Referring to FIG. 18, various electronic devices to which the display devices according to the embodiments are applied may include not only electronic devices for image display, such as a smart phone 10000_1a, a tablet PC 10000_1b, a laptop 10000_1c, a TV 10000_1d, and a desk monitor 10000_1e, but also wearable electronic devices including display modules such as smart glasses 10000_2a, a head mounted display 10000_2b, and a smart watch 10000_2c, a vehicle electronic device 10000_3 including display modules such as a vehicle dashboard, a center fascia, a center information display (CID) arranged on the dashboard, and a room mirror display.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a display panel;
a panel protection member arranged on a first major surface of the display panel in a first direction;
a panel support member arranged on a major surface of the panel protection member in a second direction opposite to the first direction;
a spacer arranged on a major surface of the panel support member in the first direction;
an adhesive member arranged on the major surface of the panel support member in the first direction and spaced apart from the spacer; and
a heat dissipation member arranged on the major surface of the panel support member in the first direction to surround sides of the spacer and the adhesive member.

2. The display device of claim 1, wherein a thickness of the heat dissipation member is thinner than each of a thickness of the spacer and a thickness of the adhesive member.

3. The display device of claim 1, wherein the side of the spacer and the side of the adhesive member are spaced apart from a side of the heat dissipation member.

4. The display device of claim 1, wherein the heat dissipation member is arranged to cover at least a portion of the major surface of the panel support member in the first direction.

5. The display device of claim 1, wherein the display panel is partitioned into a first non-bending area, a second non-bending area, and a bending area formed between the first non-bending area and the second non-bending area,
the display device further comprising:
a bending protection member arranged on a second major surface of the display panel, which is opposite to the first major surface of the display panel, in the bending area of the display panel; and
a circuit board connected to the display panel.

6. The display device of claim 5, wherein the spacer is in contact with the panel protection member arranged on the first major surface of the display panel in the second non-bending area.

7. The display device of claim 5, wherein the circuit board is connected to the second non-bending area of the display panel, and the adhesive member is in contact with the circuit board.

8. The display device of claim 5, further comprising:
a driving circuit arranged on the second major surface of the display panel in the second non-bending area;
a cover member covering the driving circuit;
a polarizing film arranged on the second major surface of the display panel in the first non-bending area; and
a cover window arranged on a major surface of the polarizing film in the second direction.

9. A display device comprising:
a display panel;
a panel protection member arranged on a first major surface of the display panel in a first direction;
a panel support member arranged on a major surface of the panel protection member in a second direction opposite to the first direction;
a heat dissipation member arranged on a major surface of the panel support member in the first direction;
a spacer arranged on a major surface of the heat dissipation member in the first direction;
an adhesive member arranged on the major surface of the heat dissipation member in the first direction and spaced apart from the spacer; and
an auxiliary heat dissipation member arranged on the major surface of the heat dissipation member in the first direction to surround sides of the spacer and the adhesive member.

10. The display device of claim 9, wherein a thickness of the auxiliary heat dissipation member is thinner than each of a thickness of the spacer and a thickness of the adhesive member.

11. The display device of claim 9, wherein a thickness of the auxiliary heat dissipation member is thicker than a thickness of the heat dissipation member.

12. The display device of claim 9, wherein the side of the spacer and the side of the adhesive member are spaced apart from a side of the heat dissipation member.

13. The display device of claim 9, wherein the heat dissipation member is arranged to cover the major surface of the panel support member in the first direction.

14. The display device of claim 9, wherein the display panel is partitioned into a first non-bending area, a second non-bending area, and a bending area formed between the first non-bending area and the second non-bending area,
the display device further comprising:
a bending protection member arranged on a second major surface of the display panel, which is opposite to the first major surface of the display panel, in the bending area of the display panel; and
a circuit board connected to the display panel.

15. The display device of claim 14, wherein the spacer is in contact with the panel protection member arranged on the first major surface of the display panel in the second non-bending area.

16. The display device of claim 14, wherein the circuit board is connected to the second non-bending area of the display panel, and the adhesive member is in contact with the circuit board.

17. The display device of claim 14, further comprising:
a driving circuit arranged on the second major surface of the display panel in the second non-bending area;
a cover member covering the driving circuit;
a polarizing film arranged on the second major surface of the display panel in the first non-bending area; and
a cover window arranged on a major surface of the polarizing film in the second direction.

18. An electronic device comprising:
a display panel;
a panel protection member arranged on a major surface of the display panel in a first direction;
a panel support member arranged on a major surface of the panel protection member in a second direction opposite to the first direction;
a spacer arranged on a major surface of the panel support member in the first direction;
an adhesive member arranged on the major surface of the panel support member in the first direction and spaced apart from the spacer;
a heat dissipation member arranged on the major surface of the panel support member in the first direction;
a processor;
a memory in which one or more data of the display panel and the processor are stored; and
a power module, which supplies a power source to the display panel, the processor, and the memory.

19. The electronic device of claim 18, wherein the heat dissipation member is arranged to surround sides of the spacer and the adhesive member.

20. The electronic device of claim 18, wherein the spacer and the adhesive member are arranged on a major surface of the heat dissipation member in the first direction, and
the electronic device further comprises an auxiliary heat dissipation member arranged on the major surface of the heat dissipation member in the first direction to surround sides of the spacer and the adhesive member.
